(19) United States
(12) Patent Application Publication
(10) Pub. No.: US 2009/0224801 A1
(43) Pub. Date: Sep. 10, 2009

(54) PATTERN MATCHING APPARATUS

(75) Inventor: Andrew Charles Lewin, Worcestershire (GB)

Correspondence Address: OLIFF & BERRIDGE, PLC, P.O. BOX 320850, ALEXANDRIA, VA, 22320-4850, US

(73) Assignee: QINETIQ LIMITED, London (GB)

(21) Appl. No.: 12/300,723

(22) PCT Filed: May 21, 2007
(86) PCT No.: PCT/GB2007/001863

§ 371 Date: Nov. 13, 2008

(30) Foreign Application Priority Data
May 26, 2006 (GB) 0610434.3

(51) Int. Cl. H03K 19/21; H03K 19/20; H03M 9/00

(52) U.S. Cl. 326/52; 326/104; 341/100

(57) ABSTRACT

A pattern matching apparatus for matching input data to a reference data string, wherein: it is implemented in electronic hardware and can be implemented using commercially available FPGAs using all digital processing; it is capable of very fast correlation; input data is received by a 1:N demultiplexer which reduces the clock speed and produces an N channel parallel data signal which is passed to an N wide, M stage shift register; the shift register has an output at each intermediate stage to produce an N by M parallel data signal, each representing a different bit of the input data; the input data is compared with reference data by combining each channel with an appropriate reference data channel using an XOR combination; the results of the bit level XOR comparisons are then combined using OR combinations, conveniently at byte level and then at string level; and the result is a simple match/no match signal.

This invention relates to a pattern matching apparatus which can act on very fast input data to determine a match, especially to an electronic pattern matching apparatus that can be implemented in commercially available electronic components.

Pattern recognition is concerned with the process of recognising one or more known objects in incoming data, for example text or imagery, by comparing known reference object(s) with the data. An ideal way to perform pattern recognition autonomously is through the mathematical operation of correlation.

There are many areas in which pattern recognition is used, from interrogating databases to locate specific search terms to biometric based recognition systems and target identification in two-dimensional imagery. Often the search is performed using a suitably programmed processor to compare a known reference data string with the data to be searched to identify a match. One example is an internet search engine which compares one or more input reference words with internet data to identify a match.

When searching very large amounts of data however software based pattern identification techniques may be slow or require very large processing power. Also when data is received at high data rates, for example at telecommunications data transfer rates, software based systems may be unable to perform correlation at this speed.

Recently it has been proposed to apply the benefits of optical correlation to high speed pattern matching. International Patent Publication WO2006/043057 describes a correlator apparatus that uses fast phase modulation and parallel optical processing to allow high speed correlation. This correlator turns an input data stream into a parallel optical phase modulated signal. A wavefront is formed which has been phase modulated by both the input data and reference data and then interferometrically combined. A detector measures the resulting light intensity. When there is no match between the input data and reference signal the optical wavefront has a random phase modulation and thus exhibits some destructive interference at the detector. However when there is a match the wavefront has matching phase and thus is constructively combined at the detector. The intensity of light reaching the detector array thus gives an indication of correlation.

Whilst the apparatus described in WO2006/043057 can operate at very high speed it does require optical components to be located in precise alignment.

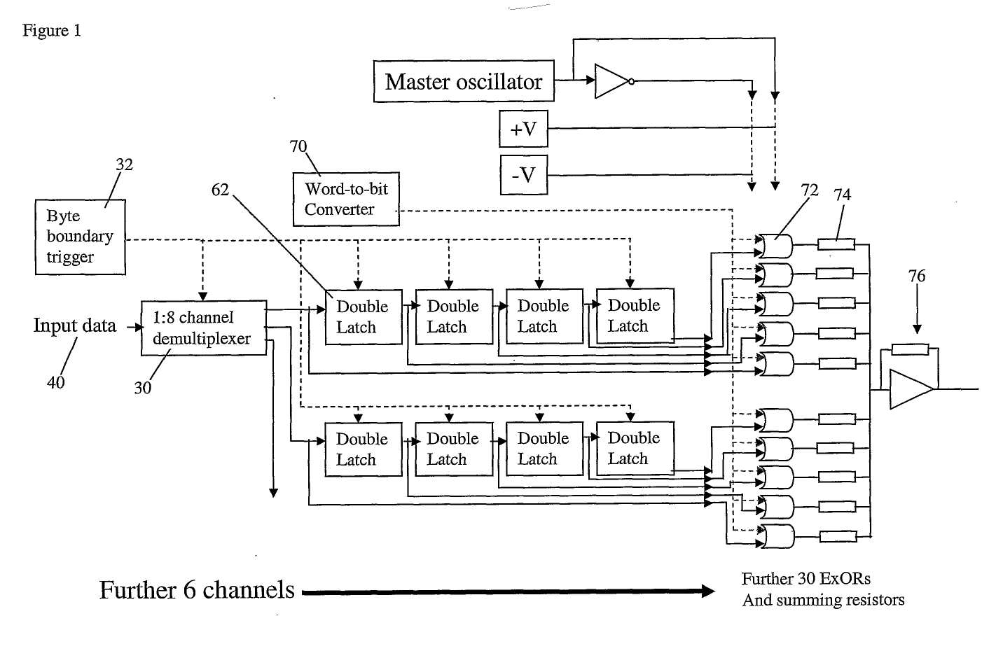

Our co-pending patent application GB0525229.1 describes a correlator which is implemented entirely in the electronic domain. FIG. 1 shows an embodiment of this correlator. Digital input data 40 is received and passed to a 1:8 demultiplexer 30 which produces a parallel signal at an eighth of the input frequency. Each output of the demultiplexer 32 is used to form one channel in the parallel electrical signal to be passed to a comparator and so is passed to one input of an exclusive OR (XOR) logic gate 72. Further each output of the demultiplexer 32 is also connected to the input of a series of four latch circuits 62₁-62₄. Each latch circuit is connected to the next. Further the output of each latch circuit is also taken as another channel of the parallel signal and connected to the input of an XOR gate 72. The latch circuits 62 are also controlled by byte boundary controller 32 and the series acts as a shift register. The data value output from the demultiplexer is therefore rippled along the series. At any update time the data output from the demultiplexer is passed to the input of one of the XOR gates 72. At the same time the first latch circuit in the series for each channel will output the previous data to the input of a different XOR gate and the second latch circuit in each series will output the data previous to that and so on. Thus a 40 channel electrical signal is formed on the inputs of the 40 XOR gates 72, which then ripples through in increments of 8 bits.

The array of XOR gates form an input to a comparator which compares the value of the binary data on each channel of the parallel input signal with the binary value from a reference parallel signal. The reference parallel signal is formed by word to bit convertor 70.

The correlation is performed on the basis of bit addition, i.e. the principle that if the particular bit in the input data matches the relevant reference bit the sum will be zero whereas if there is a mismatch the sum will be one. Thus for a complete match the sum of all the outputs from all the channels should be zero and a value of greater than zero is indicative of a mismatch. The bit addition is performed by the XOR logic arrangements 72. An XOR gate outputs a value 1 when either one, but not both, of the inputs is value 1. This gives the required result that when the both inputs to the XOR gate match, i.e. the relevant bit in the input data matches the relevant bit in the reference data, the output is zero but when there is no match the output is one.

The output of each XOR gate 72 is therefore zero for the perfect match case. An instance of a zero on each output is detected using a summing/difference circuit. The output of each XOR gate 72 is connected to a summing resistor 74 and peak/dip detection circuit 74 detects a zero sum. The combined input from all XOR gates 72 is input to transimpedance amplifier (TIA) and resistor. The output from the TIA goes to a peak holding circuit and comparator. This circuit is arranged to trigger on a zero sum indicating a perfect match. However the degree of correlation can be indicated by the voltage level at the comparator. As mentioned, if every bit of the input and reference data match, the output from each XOR is zero and the sum is also zero (or near zero allowing for noise). If the reference data and input data differ in only one bit the output of one XOR will be +V, the rest being zero, and so the sum is +V. If the data strings match but for two bits then two XOR will output +V and the sum will be +2V and so on. Thus the summed voltage level can be used as an indication of how close a match the reference and data strings are. This information could be useful when it is wished to search for close matches. However it will be noted that whilst the input data, demultiplexer, latch circuits and XOR gates all work digitally, the summing and comparison circuitry works using analogue voltage levels. The combination of digital and analogue processing means that implementing this correlator in a compact chip form requires a specific mixed signal ASIC, i.e. a custom build device. Further the use of analogue trigger circuits requires careful setting of the detection threshold. The threshold needs to be set such that noise on the signal in a perfect match case still registered as a match but a noisy close match signal is not seen as a false positive.

It would be advantageous in terms of cost and availability to provide a pattern matching apparatus which could be implemented purely using commercially available generic components, such a field programmable gate arrays (FPGAs).

Therefore according to the invention there is provided a pattern matching apparatus comprising a serial to parallel converter for receiving a digital input data stream and producing a parallel digital signal on a plurality of output channels, each output channel having an XOR logic combiner combining the input signal at each output channel with a reference data bit and a digital difference circuit acting on the output of each XOR logic combiner.

Preferably the digital difference circuit comprises a nested arrangement of OR logic combiners. As the skilled person will appreciate an OR logic arrangement will output a logic 1 if any of its inputs is a logic 1. The reference data is combined with the input data using an XOR arrangement. As described above an XOR arrangement will produce a logic 0 if the input and the reference data match, otherwise it will output a logic 1. The difference circuit uses a series of OR logic arrangements and thus will register a logic 1 if any of the outputs of the XOR combiners is a logic 1. Thus the output of the difference circuit is a logic 1 is there is any mismatch between the input data and the reference data. Only when the input data exactly matches the reference data is the output a logic 0. The present invention therefore provides a pattern matching apparatus which registers an exact match. As such it may not be suitable for some applications where a degree of similarity matching is required and an indication of the similarity is wanted. However the present inventors have realised that for several applications a search term is entered and only exact matches are required. Further, as the whole processing is done digitally, a pattern matcher according to the present invention can be implemented in a suitably programmed field programmable gate array (FPGA). Indeed a standard commercially available FPGA such as produced by Altera or Xilinx could be suitably programmed to implement a pattern matching apparatus according to the present invention several hundred times over on one chip. Each implementation could be provided with a different reference data set thus enabling parallel searching. Longer search strings could be broken down to smaller strings with a different apparatus searching for each individual part of the string. Different spellings or abbreviations could be searched for in parallel or several different search terms could be searched for.

The digital difference circuit is conveniently arranged such that the output of the XOR combiner for each bit in a byte of data is combined in a byte OR combiner and the output of each byte OR combiner is combined in a string OR combiner. As is well known in the art, digital data is generally transmitted with a certain number of bits of data, usually eight, representing a byte or packet of data. The difference circuit is arranged such that outputs of the XOR combiners, which combine each bit in a byte of input data with the appropriate bit of a byte of reference data, are all input to an OR combiner. As mentioned above an individual XOR combiner will output a logic 0 if the particular bit of the input data matches the particular bit of the reference data. The outputs of each bit comparison are then combined on a byte by byte basis. If any of the bits did not match, the OR combiner outputs a logic 1 indicating that byte was not a match. The output of each byte OR combiner is then input to a string OR combiner which again will only output a logic 0, indicating a match, if every byte in the string was a match.

The apparatus may also comprise bit enable means for selecting some or all of the bit channels for matching. It may be the case that some bits in each byte represent extraneous information for the particular application and/or it is deliberately wished to ignore one or more bits in matching the data. For instance were the bytes of data to represent ASCII character values it is noted that the one particular bit in the byte is used to represent whether the character is upper case or lower case, with the rest of the data being identical. If the search wishes to search for instances of a particular word it may not matter whether the word is in upper or lower case and each should register a hit. Therefore rather than search for each combination of upper and lower case characters one could remove the particular bit that represents the case from the comparison. Thus a hit would be generated when the right character appears with no case sensitivity. In effect, the bit enable inputs across the entire string enable “wild card” functions to be enabled should “spelling” variants be expected.

The bit enable means could comprise a switch arrangement to short circuit certain channels from consideration but a digital logic solution is preferred as it again enables the apparatus to be implemented on an FPGA. The bit enablement means therefore conveniently comprises an AND logic combiner for combining the output of each XOR combiner with a bit enable signal. If a bit is enabled the AND combiner receives a logic 1 from the bit enable means. The AND combiner will output a logic 1 only if both inputs are 1. Therefore if the signal from the XOR combiner was a logic 1 the output from the AND combiner will also be logic 1 whereas if the input were logic 0 the output would also be logic 0, i.e. when enabled the AND combiner has no effect. If the bit enable signal were 0 however the output of the AND combiner would be 0 whatever the input coming from the XOR combiner. Therefore, with a particular bit disabled, were the rest of the data a match the apparatus would register a match irrespective of whether the disabled bit matched or not.

The serial-to-parallel conversion means preferably comprises at least one 1:N demultiplexer. A demultiplexer is a known piece of equipment for performing a serial to parallel conversion and is sometimes known as a serial-to-parallel converter. The demultiplexer has an input by which it receives the input data stream and N different outputs. The demultiplexer effectively stores bits as they are received until it is storing N bits, at which point it outputs a different one of the N stored bits on each of the N outputs. It then stores the next N bits from the input signal. In this way N bits of a temporal or serial input data stream are converted into a parallel data signal.

It will be apparent that the demultiplexer therefore only outputs a signal after it has received N bits and so the output rate from the demultiplexer is slower than the bit rate of the input data stream by a factor of N. Therefore, whatever the bit rate of the input data the use of a demultiplexer reduces the subsequent update rate by a factor of N which eases system requirements and thus allows commercially available components to be used.

Most commercially available demultiplexers (at the input data rates of interest, of the order of 10-40 Gigabits a second or possibly higher) tend to be limited to 1:4 or 1:16 demultiplexers although other demultiplexers, such a 1:8 are available. Preferably, commercially available demultiplexers are used and conveniently a 1:16 demultiplexer is selected.

Eight or sixteen parallel channels is generally not sufficiently high for useful pattern matching purposes and more channels (bytes or characters) are generally required. Preferably therefore each output of the 1:N demultiplexer is connected to an M stage shift register having an output from each stage forming an output channel. The shift register is clocked at the same speed as the demultiplexer.

Thus the output from the demultiplexer on any particular output channel goes to the first stage in the shift register. This is clocked at the output rate of the demultiplexer and on each clock pulse the data is both passed to the stage in the shift register and also output to an output channel. The shift register acts as a series of (clocked) delays in the electrical domain. A 1:8 demultiplexer could therefore be used with an eight bit wide five stage shift register to give a 40 bit output.

The shift register could be an suitable shift register, including a series of latch circuits such as used in GB0525229.1. Where the invention is implemented in an FPGA the shift register function can be programmed into the FPGA.

It should be noted that for lower input data rates the use of a shift register offers the opportunity to provide a series of electrical delays, and hence perform serial to parallel conversion, without the need for a multiplexer. For instance a 39 stage shift register clocked at the actual bit rate, with an output between each stage, could convert a 40 bit long sequence into a parallel electrical signal directly. Therefore the serial-to-parallel conversion means may simply comprise a shift register with an output at each stage.

However, at high data rates sufficiently fast shift registers may not be available and use of a separate demultiplexer reduces the clock rate at which the shift register operates. Also the subsequent logic circuitry is not yet sufficiently quick to cope with very high data rates, 10 Gbits s⁻¹, that can be available using standard telecoms based hardware. However reducing the clock rate by a factor of 8 or 16 eases the requirement for the rest of the (FPGA) hardware.

The invention will now be described by way of example only with respect to the following drawings of which,

FIG. 1 shows an embodiment of an electronic correlator described in co-pending patent application no. GB0525229.1,

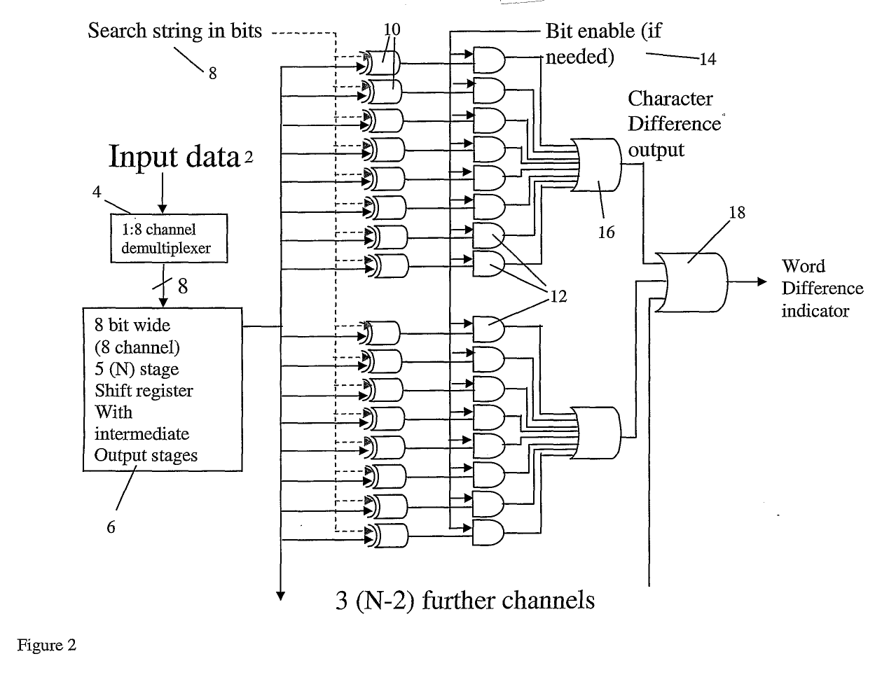

FIG. 2 shows an embodiment of a pattern matching apparatus according to the present invention,

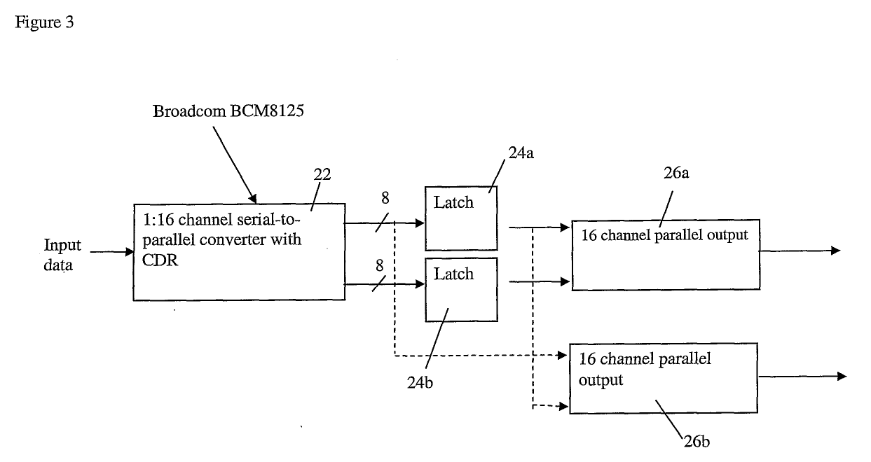

FIG. 3 shows an input arrangement for signal unpacking.

FIG. 2 shows an embodiment of the present invention. An input data signal 2, in form of amplitude modulated electrical signals, is received by a 1:8 demultiplexer 4. The skilled person will be aware of demultiplexers that can be used for the particular requirement, e.g. Inphi 5081 DX 50 Gbps 1:4 demultiplexer or Broadcom BCM8125 1:16 demultiplexer. The demultiplexer 4 is controlled by a clock signal to convert an eight bit byte in the series input data into an eight channel parallel data signal. Thus at a rate of one eighth of the bit rate of the input data the demultiplexer 4 outputs a different bit value on each of its eight output channels to an eight bit wide, five stage shift register 6.

Assuming a 10 GHz input signal the effect of the 1:8 demultiplexer is to reduce the data rate to 1.25 GHz which is within the range of operation of commercially available fast FPGA arrays. A 1:16 demultiplexer would obviously reduce the input data rate even further to 625 MHz. In some instances, it may be convenient to use a 1:32 demultiplexer (if available) if the data of interest is in 32 bit blocks. In this case, the “word-length” sought is fixed at 4 bytes long, and the data is ideally clocked 32 bits at a time. Detection of header patterns could also be used to trigger 32-bit boundaries.

Shift register 6 is clocked by the same clock signal and has an output from each of the five stages. A shift register can be implemented on the FPGA as will be understood by one skilled in the art.

This therefore provides a 40 channel parallel data channel. The data channels are conveniently arranged together in bytes (at least notionally). Each byte of input data is then combined with an appropriate bit of reference data 8 using an XOR gate 10. An XOR gate outputs a value 1 when either one, but not both, of the inputs is value 1. In other words the truth table is;

TABLE 1

| | 1 | 0 |
|---|---|---|
| 1 | 0 | 1 |
| 0 | 1 | 0 |

This gives the required result that when the both inputs to the XOR gate match, i.e. the relevant bit in the input data matches the relevant bit in the reference data, the output is zero but when there is no match the output is one.

The output of each XOR gate 10 is connected to one input of an AND gate 12. The other input of each AND gate 12 is connected to a bit enable controller 14. The bit enable controller 14 and AND gates 12 allow particular bits to be discounted from comparison.

If the input data stream is a string of ASCII code the value of each byte determines the character it represents. Whether a particular character is upper or lower case is represented by the value of one bit, all other bits being identical. Thus an upper case P and a lower case P vary from one another in one bit only. Where a search wished to be case insensitive, for instance one wishes to search for instances of “patent” and/or “Patent”, this can be easily implemented by ignoring the bit in each byte which indicates case.

The bit enable input of each AND gate for a bit to be enabled is set to 1. An AND gate produces an output of 1 only when both inputs are 1, i.e. the truth table is;

TABLE 2

| | 1 | 0 |
|---|---|---|
| 1 | 1 | 0 |
| 0 | 0 | 0 |

Therefore it can be seen that when the bit enable input is 1 the output of the AND gate 12 matches the output on the input received from the XOR gate 10. However when the bit enable input is 0 the output is 0 whatever the other input. Thus with a bit enable signal of 0 supplied to the AND gate on a particular channel that channel will be constantly set at zero.

The outputs from the outputs of each AND gate 10 for a particular byte are combined in a byte difference combiner 16, either an eight channel OR arrangement or a series of nested OR gates. The result is the same though, if any of the individual bit comparisons on an enabled channel resulted in a logic 1, indicating a mismatch, the byte difference output is also a logic 1.

Each of the five byte difference outputs are combined in a string difference OR combiner 18 which again outputs a logic 1 if any of the outputs of the byte difference combiners was a logic 1.

This embodiment is an all digital electronic pattern matching apparatus which can provide fast pattern matching at input data rates of 10 Ghz or higher and which can be readily implemented on an FPGA. When searching data in ASCII code the search can be case insensitive if required.

When a 1:8 demultiplexer is used the parallel data signal formed by the shift register effectively changes one byte, or one character at a time. Thus, for instance, were a 1:8 demultiplexer used with a six stage shift register to create a 48 bit (or six byte) parallel signal and the input data string was the number sequence from one to twenty, the parallel data signal at a first time would correspond to “1, 2, 3, 4, 5, 6”. At the next clock time it would be “2, 3, 4, 5, 6, 7” and so on. Therefore if the search string were the sequence “8, 9, 10, 11, 12, 13” the apparatus would generate a hit at the right time.

However were a 1:16 demultiplexer used, to reduce the data rate, each update of the parallel data signal would be two bytes of data. If this were used with a three stage shift register to again create a six byte parallel signal the signal at a first time would again be “1, 2, 3, 4, 5, 6”. However at the next clock time it would change to “3, 4, 5, 6, 7, 8” and then “5, 6, 7, 8, 9, 10” after that and so on. Thus a search for the string “8, 9, 10, 11, 12, 13” would not generate a hit even though the string had been present in the input data.

To get around this problem multiple reference patterns could be used. Three separate pattern matching apparatuses would be required. One could search for the search string “8, 9, 10, 11, 12, 13” as discussed. A second could have the reference pattern displaced by one byte, i.e. it would search for “*, 8, 9, 10, 11, 12”. The * indicates it does not matter what this character is, which could be achieved, as described above, by disabling all of bits in the first byte. However this reference pattern obviously does not contain the whole search string and so the third pattern matcher would search for the reference string “13, *, *, *, *, *” occurring exactly one clock period after a match on the second pattern matcher. This is clearly inefficient, ideally requiring longer strings with wild cards at each end.

A more attractive solution is to unpack the demultiplexed signal so as to ensure each possible combination is searched. FIG. 3 shows such an unpacking apparatus.

The input data goes to a 1:16 demultiplexer 22 which produce 16 parallel channels, i.e. two bytes of data. Each byte of data is passed to a latch circuit 24a, 24b which holds the data for one clock period before passing it to a sixteen channel output 26a. Eight outputs channels from 1:16 demultiplexer 22, those corresponding to the later byte, are also connected to a second sixteen channel output 26b, without going through the latch circuit. The other eight outputs from the 1:16 demultiplexer are also input to the sixteen channel output 26b but only after having been through latch circuit 24a. Sixteen channel output 26b therefore produces different 16 bit parallel signal.

Consider then what happens if data corresponding to the characters one to twenty is input to this arrangement. In a first clock time demultiplexer 22 will output a two byte parallel signal corresponding to the numbers 1 and 2, in the next period the numbers 3 and 4, then 5 and 6 and so on. These bytes will go through latch circuits 24a and 24b to form an output. Thus output 26a will consist of the parallel signals “1, 2”, “3, 4”, “5, 6” and so on. Output 26b however receives one input directly from the 1:16 demultiplexer and another delayed output of the previous byte, i.e. it will output “2, 3”, “4, 5”, “5, 6” and so on. Each of these sixteen channel parallel signals could then go to a pattern matcher according to the present invention looking for the same reference string. The idea could obviously be extended to create larger parallel signals to search for longer strings. It remains true, however, that although using a 1:32 demultiplexer will lower the input bandwidth at the FPGA, thus easing the speed requirements by a factor of 4, it will require 4 search engines, thus reducing the dictionary size which can be searched by that same factor. In practice, the best overall system specification will be achieved when the input rate to the FPGA is at it's highest.

1. A pattern matching apparatus comprising a serial to parallel converter for receiving a digital input data stream and producing a parallel digital signal on a plurality of output channels, each output channel having an XOR logic combiner combining the input signal at each output channel with a reference data bit and a digital difference circuit acting on the output of each XOR logic combiner.

2. A pattern matching apparatus as claimed in claim 1 wherein the digital difference circuit comprises a nested arrangement of OR logic combiners.

3. A pattern matching apparatus as claimed in claim 1 wherein the digital difference circuit is arranged such that the output of the XOR combiner for each bit in a byte of data is combined in a byte OR combiner and the output of each byte OR combiner is combined in a string OR combiner.

4. A pattern matching apparatus as claimed in claim 1, further comprising bit enable means for selecting some or all of the bit channels for matching.

5. A pattern matching apparatus as claimed in claim 4 wherein the bit enable means comprises an AND logic combiner for combining the output of each XOR combiner with a bit enable signal.

6. A pattern matching apparatus as claimed in claim 1, wherein the serial-to-parallel conversion means comprises at least one 1:N demultiplexer.

7. A pattern matching apparatus as claimed in claim 6 wherein each output of the 1:N demultiplexer is connected to an M stage shift register having an output from each stage forming an output channel.

8. A field programmable gate array device configured to implement a pattern matching apparatus as claimed in claim 1.
